(19) United States
(12) Patent Application Publication
(10) Pub. No.: US 2025/0028195 A1
(43) Pub. Date: Jan. 23, 2025

(54) Wafer-Level Poling of Electro-Optic Phase Modulators

(71) Applicant: Lightwave Logic, Inc., Englewood, CO (US)

(72) Inventor: Jasper Altman Drisko, Portland, ME (US)

(73) Assignee: Lightwave Logic, Inc., Englewood, CO (US)

(21) Appl. No.: 18/778,171

(22) Filed: Jul. 19, 2024

Related U.S. Application Data
(60) Provisional application No. 63/527,984, filed on Jul. 20, 2023.

(51) Int. Cl. G02F 1/065; H05K 1/18; H05K 3/30

(52) U.S. Cl. CPC G02F 1/065; H05K 1/181; H05K 3/303; G02F 2203/50; H05K 2201/10181

(57) ABSTRACT

A method of fabricating an integrated electro-optic phase modulator array is described. The method may include providing a first substrate. The first substrate may include an interconnect array. The method may include arranging an array of electro-optic phase modulators on a surface of the first substrate. Each electro-optic phase modulator may include a polymer optical stack, a semiconductor substrate, an electric input, an optical input, and/or an optical output. The interconnect array in each modulator may include an electrical interconnect, an electrical bypass, and/or an optical interconnect. The electrical interconnect may connect to a respective electrical input. The electrical bypass may connect at least a pair of adjacent modulators. The optical interconnect may connect a respective optical input and optical output. Each modulator may be series connected to a respective fuse arranged along the electric interconnect between the respective electric input and a voltage source.

### CROSS-REFERENCE TO RELATED APPLICATIONS

This application claims the benefit of U.S. Provisional Application No. 63/527,984 filed on Jul. 20, 2023, the entire contents of which is incorporated herein by reference

### BACKGROUND

The disclosed inventions generally relate to polymer modulators. Polymer modulators have become very popular in the current technology boom. Polymer photonics technology with customized core and cladding layers provides a number of significant advantages over the prior art. Among the many advantages, some of the most significant are that it allows efficient 3-layer modulators with high performance (multi-GHz) and very-low voltage operation to allow direct-drive without the need for using a drive circuit. While this technique has been commercialized it is not optimized. That is, it does not reach the low-cost targets, or space/size requirements, and takes lots of time to align the components, place them, package them, and test them.

Much of the recent work on polymer modulators has been focused on Si-organic-hybrids (SOH) often referred to as Si slot modulators. These modulators exhibit very small V_{π}-L products due to their short length (^{˜}1 mm) and high single-layer r₃₃ coefficients. Due to the fact that only an electro-optic (EO) polymer is used in the structure, the poling is efficient and the single-layer r₃₃ (value achieved in a Teng-Man measurement) is also achieved in the device. This is contrasted with a typical 3-layer modulator (cladding/core/cladding) where the poling is inefficient due to the voltage division among the three layers. Typically, dielectric breakdown occurs in the cladding before complete poling can be accomplished in the core.

Wafer-level poling to pole a whole wafer improves the efficiency in the semiconductor industry. Efficient poling typically poles the whole wafer with a plurality of slot modulator devices (e.g., hundreds of slot modulator devices or thousands of slot modulator devices). A high-voltage constant voltage source that provides the high voltage may be series connected with the plurality of slot modulator devices to provide power to each slot modulator device to pole at the same time.

When one slot modulator device in the plurality of slot modulator devices shorts, the current in the circuit will travel through the shorted device. Meanwhile, when one slot modulator device shorts, other slot modulator devices may no longer have any current passing through or may not have any voltage drop over them. Since Joule heating caused by the current is proportionally related to the square of the current, the increased current will cause high Joule heating on the fuse connected to the shorted device. The fuse connected to the whole circuit may break under the high Joule heating and disconnect the circuit to protect every device in the wafer-level poling. If the fuse connected to the whole circuit breaks and disconnects the whole circuit, the disconnection of the whole circuit may stop other slot modulator devices from working as well since no current is now passing through other slot modulator devices.

The present invention may include a plurality of fuses connected in parallel. Each fuse in the present invention may be connected in series to a limited number of slot modulator devices (e.g., one slot modulator device). If one fuse that is series connected to a shorted slot modulator device breaks, the fuses that are not connected in series can still function because they still can receive current. When the fuse that is series connected to the shorted slot modulator(s) breaks, the current to all the other fuses increases to take up the current that is no longer flowing through the broken fuse. However, because the current from one fuse is distributed over a large number of other fuses, the overall increase on any one fuse does not cause a spike that can cause that fuse to break. Therefore, according to one aspect, the present invention not only provides protection to other devices and the whole circuit, but also keeps other devices working without stopping when there is a short.

### BRIEF SUMMARY

Methods and systems for fabricating an integrated electro-optic phase modulator array are described. The method may include providing a first substrate. The first substrate may include an interconnect array. The method may include arranging an array of electro-optic phase modulators on a surface of the first substrate. Each electro-optic phase modulator may include a polymer optical stack, a semiconductor substrate, an electric input, an optical input, and/or an optical output. The interconnect array in each modulator may include an electrical interconnect, an electrical bypass, and/or an optical interconnect. The electrical interconnect may connect to a respective electrical input. The electrical bypass may connect at least a pair of adjacent modulators. The optical interconnect may connect a respective optical input and optical output. Each modulator may be series connected to a respective fuse arranged along the electric interconnect between the respective electric input and a voltage source.

In one aspect, a system to pole a plurality of slot modulator devices simultaneously from a single high-voltage source is described. The system may include a single high-voltage input lead, a fuse array comprising a plurality of fuses connected in parallel to the high-voltage input lead, and a wafer comprising a plurality of slot modulators. Each fuse in the fuse array may have an input end series connected to the high-voltage input lead and an output end series connected to an output cable. At least one fuse in the fuse array may have a predetermined poling current upper limit. The fuse may break if the upper limit is exceeded. One or more (e.g., each) slot modulator devices in the plurality of slot modulators may be connected in series to one fuse in the fuse array through the output cable of the fuse.

In another aspect, the system may include a high-voltage input lead, a fuse array including a plurality of fuses connected in parallel to the high-voltage input lead, a probe set including a plurality of probes connected in parallel, and a wafer including a plurality of slot modulators. At least one fuse (e.g., each fuse) in the fuse array may have an input end series connected to the high-voltage input lead and an output end series connected to an output cable. At least one fuse (e.g., each fuse) in the fuse array may have a predetermined poling current upper limit. The fuse may break if the upper limit is exceeded. At least one probe (e.g., each probe) in the probe set may have an input end series connected to the output cable of a fuse in the fuse array. At least one probe (e.g., each probe) may be series connected to a slot modulator device. Multiple slot modulator devices in the plurality of slot modulators may be connected in series to one fuse in the fuse array through the probe.

In some embodiments, a high-voltage source may be series connected to the system. In some embodiments, the fuse array may be located on a carrier printed circuit board (PCB). In some embodiments, the fuse array may be equal to or more than 10,000 fuses. In some embodiments, each fuse may have a dogbone-shaped top view. Preferably, the dogbone-type fuse has a blow current, or break point, between about 500 nA and about 1000 nA. In some embodiments, each fuse may be made of aluminum or gold. In some embodiments, a metal thickness of each fuse may be about 1 μm. In some embodiments, an outer width of each fuse may be about 100 μm. An inner width of each fuse may be between about 2 μm and about 25 μm. An inner length of each fuse may be between about 50 μm and about 200 μm. A whole length of each fuse may be between about 250 μm and about 400 μm.

In some embodiments, each slot modulator device may be a silicon-organic-hybrid (SOH) slot modulator.

Because at least some fuses are connected in parallel, when one slot modulator device shorts, the fuse that is series-connected to the shorted slot modulator device will break due to Joule heating. If the fuse series connected to the shorted slot modulator device breaks, the remaining fuses connected in parallel can still function because they are still receiving current. When the fuse series connected to the shorted slot modulator breaks under a constant voltage source, the current to all the other fuses that are connected in parallel remains stable. Therefore, the various embodiments herein not only provide protection to other devices and the whole circuit, but also keep other devices working without stopping.

### BRIEF DESCRIPTION OF SEVERAL VIEWS OF THE DRAWINGS

The foregoing summary, as well as the following detailed description of preferred embodiments of the invention, will be better understood when read in conjunction with the appended drawings. For purposes of illustration of the invention, there are shown in the drawings embodiments which are presently preferred. It should be understood, however, that the invention is not limited to the precise arrangements and instrumentalities shown.

FIG. 1 is a diagram illustrating the creation of optical output with data by passing the optical input through an optical modulator device (e.g., Mach-Zehnder interferometer).

FIG. 2A is a partial side sectional diagram of an integrated electro-optic circuit.

FIG. 2B is a partial cross-sectional diagram of the integrated electro-optic circuit of FIG. 2A.

FIG. 3 is a schematic view of an embodiment of the system to pole a plurality of slot modulator devices of the present invention wherein each fuse in the fuse array is connected in series to a predetermined probe on a probe card.

FIG. 4 is an expanded schematic view of the fuse array of FIG. 3.

FIG. 5 is an expanded schematic plan view of the dogbone-shaped fuse of FIG. 3 and FIG. 4.

FIGS. 6A-6B are schematic views of alternative embodiments of the system to pole a plurality of slot modulator devices of the present invention wherein each fuse in the fuse array is connected in series to a preselected slot modulator device on a wafer.

### DETAILED DESCRIPTION

Electro-optic (EO) materials enable interactions between applied electric fields and light passing through them. The electro-optic may change the refractive index seen by the light with minimum loss. The result of being electro-optical may be an instantaneous and accurate conversion of an electrical signal to an optical signal. Optical signals may be better for transmission over distance: an increasingly useful feature as digital signal speeds are now reaching the GHz and THz ranges and the corresponding electrical transmission distances are shrinking to meters and centimeters.

EO polymers may be superior in speed and sensitivity to electrical field to traditional electro-optic materials (e.g., lithium niobate, indium phosphide and silicon). The EO polymers are hyperpolarizable, which means their electron clouds are easily pulled into a different shape by the applied electric field, changing their optical properties (e.g., index of refraction).

EO polymers may be poled to become electro-optic by applying a strong electric field along with heat. The heated EO polymers may be soft, which allows the chromophore molecules suspended in the host polymer to align in the same direction via poling. Cooling the poled material after the molecules are in place may trap them in their active state even after the poling field is removed.

Nonlinear optical (NLO) chromophores provide the EO activity in poled, electro-optic polymer devices. Electro-optic polymers have been investigated for many years as an alternative to inorganic materials such as lithium niobate in electro-optic devices. Electro-optic devices may include, for example, external modulators for telecom, datacom, RF photonics, and optical interconnects and so forth. Polymeric electro-optic materials have demonstrated enormous potential for core application in a broad range of next-generation systems and devices, including electro-optic modulators, optical switches, phased array radar, satellite and fiber telecommunications, cable television (CATV), optical gyroscopes for application in aerial and missile guidance, electronic counter measure (ECM) systems, backplane interconnects for high-speed computation, ultraquick analog-to-digital conversion, land mine detection, radio frequency photonics, spatial light modulation and all-optical (light-switching-light) signal processing.

Many NLO molecules (chromophores) have been synthesized that exhibit high molecular electro-optic properties. The product of the molecular dipole moment (μ) and hyperpolarizability (β) is often used as a measure of molecular electro-optic performance due to the dipole's involvement in material processing. See Dalton et al., “New Class of High Hyperpolarizability Organic Chromophores and Process for Synthesizing the Same”, WO 00/09613.

Hyperpolarizable organic chromophores are generally formed as molecules having a structure D-π-A, where D is an electron donor structure, A is an electron acceptor structure having a relatively higher electron affinity than the electron donor structure D, and π is a π-orbital conjugated bridge that freely permits electron flow between the donor D and the acceptor A. The molecules are generally linear and nominally polar due to the difference in electron affinities between the donor D and acceptor A. Such molecules may be poled into alignment by applying an electrical poling field during manufacture, the acceptor A portions being drawn toward a positive potential and the donor D portions being drawn toward a negative potential. The molecules may then be locked into the desired alignment by cross-linking or freezing a polymer matrix in which the chromophores are embedded. Alternatively, the chromophores may be covalently bound or otherwise substantially fixed in their poled positions.

An acceptor is an atom or group of atoms that has a low reduction potential, wherein the atom or group of atoms can accept electrons from a donor through a Π-bridge. The acceptor (A) has a higher electron affinity than does the donor (D), so that, at least in the absence of an external electric field, the chromophore is generally polarized in the ground state, with relatively more electron density on the acceptor (D). Typically, an acceptor group contains at least one electronegative heteroatom that is part of a pi bond (a double or triple bond) such that a resonance structure can be drawn that moves the electron pair of the pi bond to the heteroatom and concomitantly decreases the multiplicity of the pi bond (i.e., a double bond is formally converted to single bond or a triple bond is formally converted to a double bond) so that the heteroatom gains formal negative charge. The heteroatom may be part of a heterocyclic ring. Exemplary acceptor groups include but are not limited to —NO₂, —CN, —CHO, COR, CO₂R, —PO(OR)₃, —SOR, —SO₂R, and —SO₃R where R is alkyl, aryl, or heteroaryl. The total number of heteroatoms and carbons in an acceptor group is about 30, and the acceptor group may be substituted further with alkyl, aryl, and/or heteroaryl.

Suitable electron-accepting groups “A” (also referred to in the literature as electron-withdrawing groups) for nonlinear optical chromophores that can be used in accordance with the various embodiments of the present invention include those described in published U.S. Patent Applications: US 2007/0260062; US 2007/0260063; US 2008/0009620; US 2008/0139812; US 2009/0005561; US 2012/0267583A1 (collectively referred to as “the prior publications”), each of which is incorporated herein by reference in its entirety; and in U.S. Pat. Nos. 6,584,266; 6,393,190; 6,448,416; 6,44,830; 6,514,434; 5,044,725; 4,795,664; 5,247,042; 5,196,509; 4,810,338; 4,936,645; 4,767,169; 5,326,661; 5,187,234; 5,170,461; 5,133,037; 5,106,211; and 5,006,285; each of which is also incorporated herein by reference in its entirety.

A donor includes an atom or group of atoms that has a low oxidation potential, wherein the atom or group of atoms can donate electrons to an acceptor “A” through a Π-bridge. The donor (D) has a lower electron affinity than does the acceptor (A), so that, at least in the absence of an external electric field, the chromophore is generally polarized, with relatively less electron density on the donor (D). Typically, a donor group contains at least one heteroatom that has a lone pair of electrons capable of being in conjugation with the p-orbitals of an atom directly attached to the heteroatom such that a resonance structure can be drawn that moves the lone pair of electrons into a bond with the p-orbital of the atom directly attached to the heteroatom to formally increase the multiplicity of the bond between the heteroatom and the atom directly attached to the heteroatom (i.e., a single bond is formally converted to double bond, or a double bond is formally converted to a triple bond) so that the heteroatom gains formal positive charge. The p-orbitals of the atom directly attached to the heteroatom may be vacant or part of a multiple bond to another atom other than the heteroatom. The heteroatom may be a substituent of an atom that has pi bonds or may be in a heterocyclic ring. Exemplary donor groups include but are not limited to R₂N— and RₐX¹—, where R is alkyl, aryl or heteroaryl, X¹ is O, S, P, Se, or Te, and n is 1 or 2. The total number of heteroatoms and carbons in a donor group may be about 30, and the donor group may be substituted further with alkyl, aryl, or heteroaryl.

Suitable electron-donating groups “D” for nonlinear optical chromophores that can be used in accordance with the various embodiments of the present invention include those described in published U.S. Patent Applications: US 2007/0260062; US 2007/0260063; US 2008/0009620; US 2008/0139812; US 2009/0005561; US 2012/0267583A1 (collectively referred to as “the prior publications”), each of which is incorporated herein by reference in its entirety; and in U.S. Pat. Nos. 6,584,266; 6,393,190; 6,448,416; 6,44,830; 6,514,434; 5,044,725; 4,795,664; 5,247,042; 5,196,509; 4,810,338; 4,936,645; 4,767,169; 5,326,661; 5,187,234; 5,170,461; 5,133,037; 5,106,211; and 5,006,285; as well as U.S. patent application Ser. No. 17/358,960, filed on Jun. 25, 2021; each of which is also incorporated herein by reference in its entirety.

A “Π-bridge” includes an atom or group of atoms through which electrons may be delocalized from an electron donor (defined above) to an electron acceptor (defined above) through the orbitals of atoms in the bridge. Typically, the orbitals will be p-orbitals on double (sp²) or triple (sp) bonded carbon atoms such as those found in alkenes, alkynes, neutral or charged aromatic rings, and neutral or charged heteroaromatic ring systems. Additionally, the orbitals may be p-orbitals on atoms such as boron or nitrogen. Additionally, the orbitals may be p, d or f organometallic orbitals or hybrid organometallic orbitals. The atoms of the bridge that contain the orbitals through which the electrons are delocalized are referred to here as the “critical atoms.” The number of critical atoms in a bridge may be a number from 1 to about 30. The critical atoms may be substituted with an organic or inorganic group. The substituent may be selected with a view to improving the solubility of the chromophore in a polymer matrix, to enhance the stability of the chromophore, or for other purpose.

After poling, an electrical modulation field may be imposed through the volume of chromophores. For example, if a relatively negative potential is applied at the negative end and a relatively positive potential applied at the positive end of the poled chromophores, the chromophores will at least partially become non-polar. If a relatively positive potential is applied at the negative end and a relatively negative potential is applied at the positive end, then the chromophores will temporarily hyperpolarize in response to the applied modulation field. Generally, organic chromophores respond very quickly to electrical pulses that form the electrical modulation field and also return quickly to their former polarity when a pulse is removed.

A region of poled hyperpolarizable organic chromophores generally possesses a variable index of refraction to light. The refractive index is a function of the degree of polarization of the molecules. Thus, light that passes through an active region will propagate with one velocity in a first modulation state and another velocity in a second modulation state. This property, along with the fast response time and a relatively high sensitivity to changes in electric field state make hyperpolarizable organic chromophores excellent bases from which to construct very high speed optical modulators, phase shifters, etc.

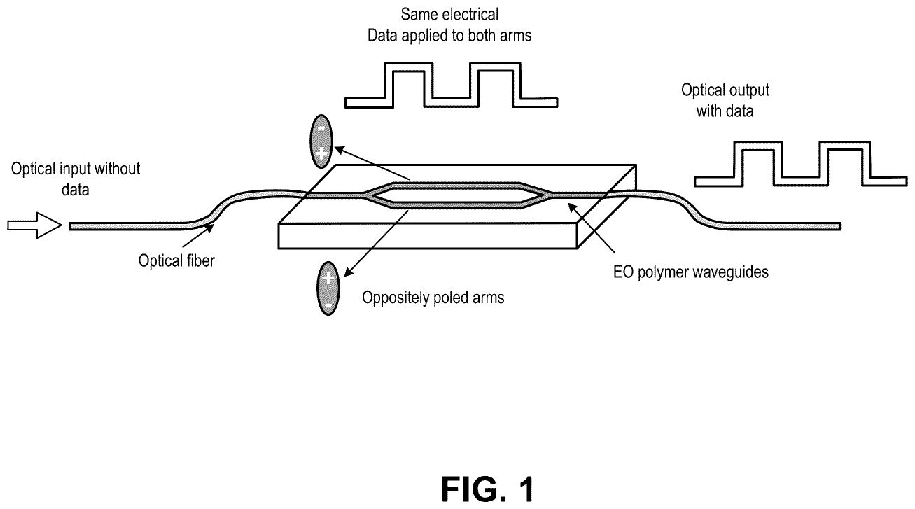

EO polymer materials, as well as other ancillary materials, may be brought together and demonstrated in high-speed optical modulators. Generally, the EO polymer materials are spun onto silicon wafers and standard microfabrication techniques are used to deposit and pattern metal electrodes and optical waveguides. In general, the electro-optic modulators may include a polymer optical stack, a semiconductor substrate, an electric input, an optical input, and/or an optical output. For example, one well-known optical modulator device is the Mach-Zehnder interferometer as shown in FIG. 1. An optical input without data that pass through the Mach-Zehnder interferometer may be transformed into an optical output with data. The optical output is changed by changing the relative phase between the two arms. One common trick to double the effect for the same available drive voltage is to drive the two arms in opposite directions (push-pull mode). Polymers have an interesting advantage over most other electro-optic materials which are crystalline. The direction of polymer's electro-optic activity is entirely determined by the direction of the applied poling field. By poling the two arms of the Mach-Zehnder in opposite directions, the resulting device automatically has push-pull operation with a single applied signal.

A plurality of electro-optic modulators may form an integrated electro-optic modulator array, which may include, e.g., an interconnect array. For each modulator, the interconnect array may include an electric interconnect, an electric bypass, and/or an optical interconnect. The electric interconnect may connect to one or more electric inputs. The electric bypass may connect at least a pair of adjacent modulators. In examples, the optical interconnect may connect to an optical input and an optical output.

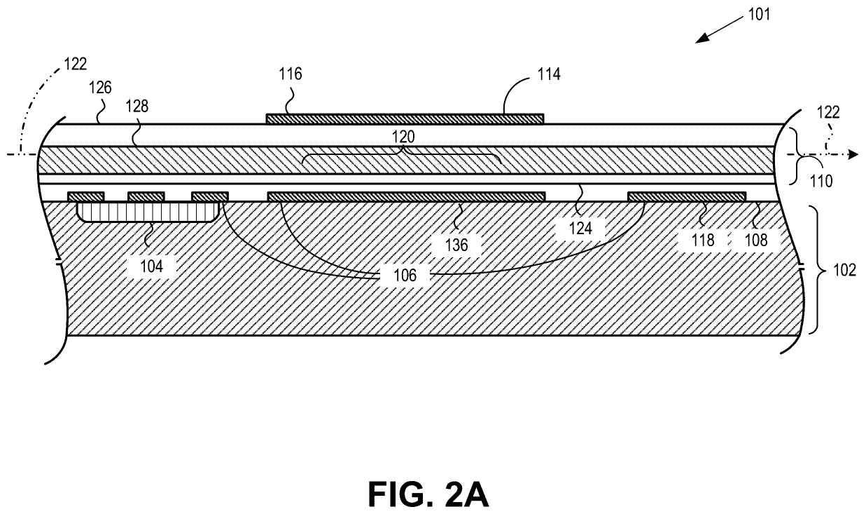

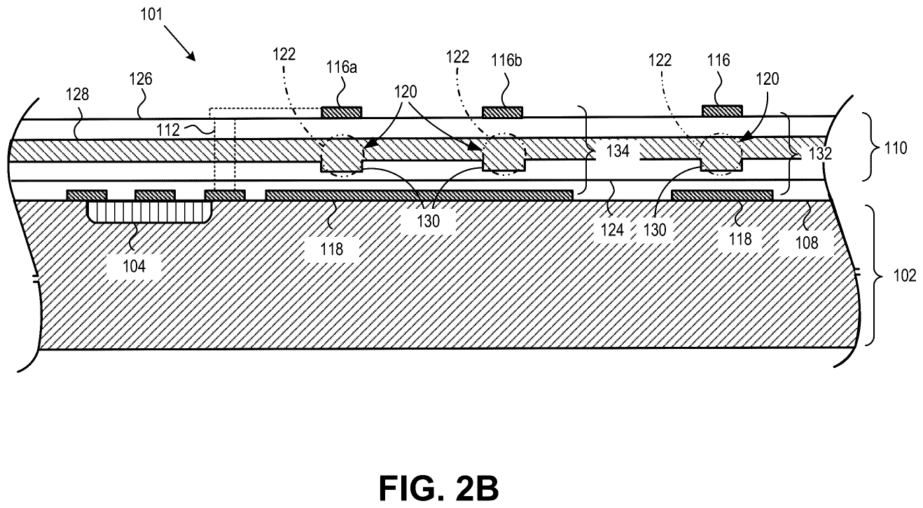

FIGS. 2A and 2B are respective side sectional and cross-sectional views of an integrated polymer electro-optic semiconductor circuit 101, according to an embodiment. A semiconductor substrate 102 includes at least one doping layer 104 patterned across the semiconductor substrate to form portions of semiconductor devices. At least one conductor layer 106 is patterned over the semiconductor substrate. A planarization layer 108 is disposed at least partly coplanar with the at least one conductor layer 106. A polymer optical stack 110 is disposed over the planarization layer 108.

At least one via 112 may at least partially extend through the polymer optical stack 110. The at least one via may be operatively coupled to a corresponding location on the at least one patterned conductor layer 106. A top conductor layer 114 is disposed over the polymer optical stack and in electrical continuity with the at least one via 112.

As an alternative to a via 112, other conductors may be substituted to electrically couple the top conductor layer to at least one location on the at least one patterned conductor layer 106. For example, the at least one conductor may be formed entirely or in combination from a via, a wire bond, a conductive bump, and/or an anisotropic conductive region.

The top conductor layer 114 may be formed to include a metal layer or a conductive polymer, for example. The top conductor may be plated to increase its thickness. The top conductor layer may include at least one high speed electrode 116 formed as a pattern in the top conductor layer 114, the high speed electrode 116 being operatively coupled to receive a signal from the at least one via 112 or other conductive structure from the corresponding location on the at least one patterned conductor layer 106. Thus, the at least one via 112 or other conductive structure is configured to transmit an electrical signal from semiconductor electrical circuitry formed on the semiconductor substrate 102 to the at least one high speed electrode 116 through or around the polymer optical stack 110.

According to embodiments, the at least one patterned conductor layer 106 is configured to form a ground electrode 118 parallel to the at least one high speed electrode 116. An active region 120 of the polymer optical stack 110 is positioned to receive a modulation signal from the high speed electrode 116 and the ground electrode 118. The active region 120 includes a poled region that contains at least one hyperpolarizable organic chromophore.

The polymer optical stack 110 is configured to support the active region 120 as well as receive and guide light 122 to and from the active region. The polymer optical stack 110 may include at least one bottom cladding layer 124 and at least one top cladding layer 126 disposed respectively below and above an electro-optic layer 128. The bottom 124 and top 126 cladding layers, optionally in cooperation with the planarization layer 108, are configured to guide inserted light 122 along the plane of the electro-optic layer 128. Light guiding structures 130 are formed in the polymer optical stack 110 to guide the light 122 along one or more light propagation paths through the electro-optic layer 128 and/or non-active core structures (not shown). In the embodiment of FIGS. 2A and 2B, the guidance structures 130 are formed as trench waveguides that include etched paths in the at least one bottom cladding layer 124.

The integrated polymer electro-optic semiconductor circuit 101 includes a semiconductor electrical circuit formed from a complex of the doping layer pattern 104 and the at least one patterned conductor layer 106. According to an embodiment, the semiconductor electrical circuit is configured, when in operation, to drive the electrodes 116, 118 with a series of modulated electrical pulses. A resultant modulated electrical field is thus imposed across the active region 120 and results in modulated hyperpolarization of the poled organic chromophores embedded therein. A complex of electrodes 116, 118, active region 120 and light guidance structures 130. The modulated hyperpolarization may thus modulate the velocity light passed through the poled active region 120 of the polymer optical stack 110. Repeatedly modulating the velocity of the transmitted light creates a phase-modulated light signal emerging from the active region. Such an active region 120 may be combined with light splitters, combiners (not shown), and other active regions to create light amplitude modulators, such as in the form of a Mach-Zehnder optical modulator.

A combination of at least one electro-optic active region 120, at least two electrodes 116, 118, and corresponding light guiding structures 124, 126, 130 may be considered an electro-optic device 132, 134. A two-channel electro-optic device 134 may be formed from one ground electrode 118 and corresponding pairs of active regions 120 and high speed electrodes 116a, 116b. The two channels of a two channel electro-optic device 134 may operate in cooperation, such as in a push-pull manner to form a Mach Zehnder optical modulator.

Additional devices may be formed using electrodes or resistors 136 that are not configured for high speed operation. The operation of one such illustrated device is described below in conjunction with the description of an optical phase bias device.

Wafer-level poling is used to pole one or more whole wafers with multiple slot modulator devices in parallel. Wafer-level poling for each whole wafer may be conducted under high voltage. The high voltage may create a corresponding high current in wafer-level poling. The high-voltage current in wafer-level poling may be a current between about 10 nA and about 100 nA. For example, a single high-voltage source may provide the high voltage current for the wafer-level poling. The single high-voltage source may also create a single high-voltage current. However, if a short circuit happens in one device during wafer-level poling, the high-voltage current may dramatically increase to a very high level (e.g., 90 μA). Under this circumstance, the high-voltage current may damage other devices and the whole circuit.

A fuse may be used to protect devices and the whole circuit. When a short circuit happens in a constant volume circuit, the current may travel through the shorted device. Meanwhile, when one slot modulator device shorts, other slot modulator devices may no longer have any current passing through or may not have any voltage drop over them. Since Joule heating caused by the current is proportionally related to the square of the current, the increased current which travels through the shorted device may cause high Joule heating on any fuse or device connected in series with the shorted device. If no fuse is available in the circuit, the other devices connected in parallel with the shorted device may stop working as a result of no voltage drop on the other devices. However, if other fuses are available in the circuit, the fuse associated with the shorted device will break due to Joule heating, thereby disconnecting the shorted device from the system and keep the voltage drop on the other devices. This can protect the circuit and other devices in the circuit.

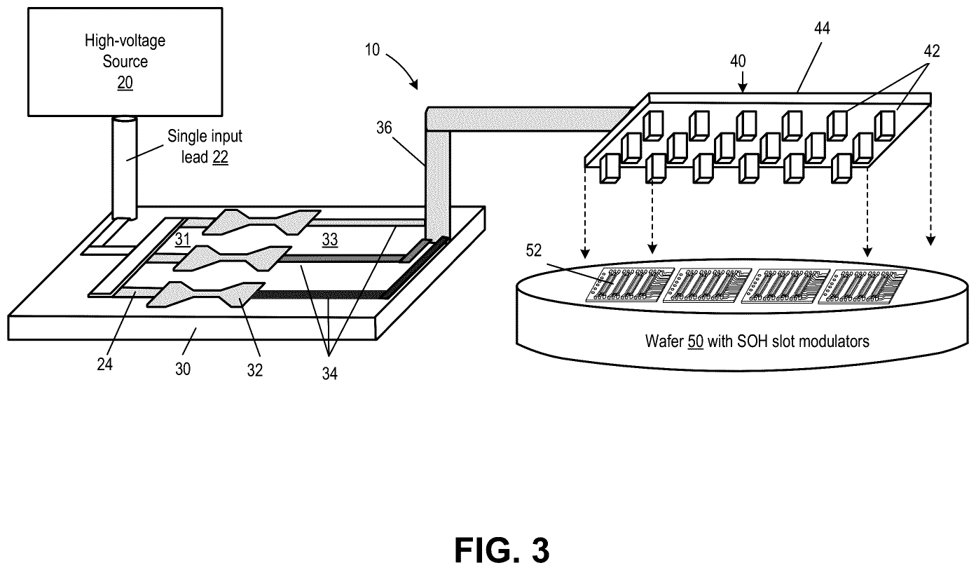

Various embodiments in wafer-level poling to pole each whole wafer includes a system to pole a plurality of slot modulator devices substantially simultaneously from the single high-voltage current. As shown in FIG. 3, in an exemplary embodiment, the system 10 may include a fuse array 30, a probe card 40, and a wafer 50 that includes a plurality of slot modulators 52. The slot modulators 52 may be fabricated on a wafer 50. The fuse array 30 may include a plurality of individual fuses 32 connected in parallel, wherein each fuse 32 is adapted to be series connected to a high voltage source 20 and to the slot modulator 52.

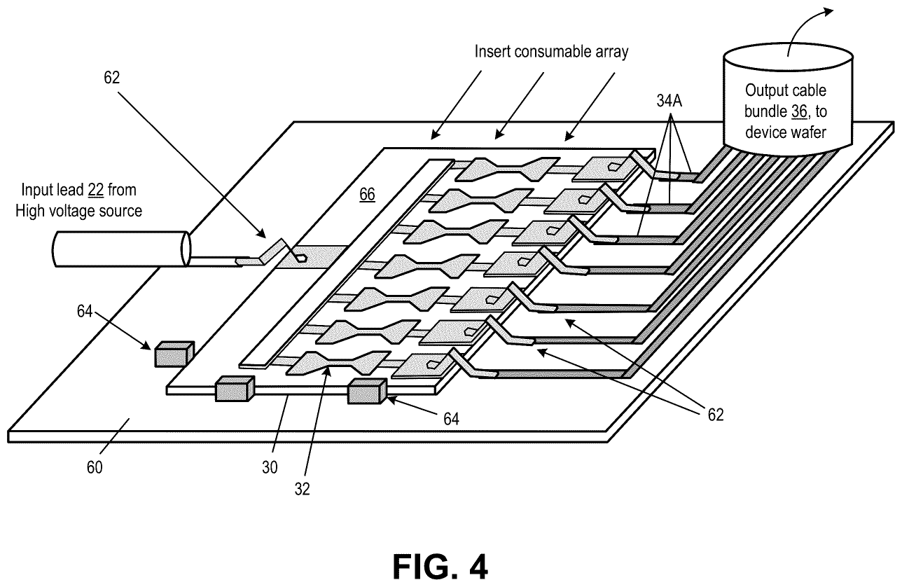

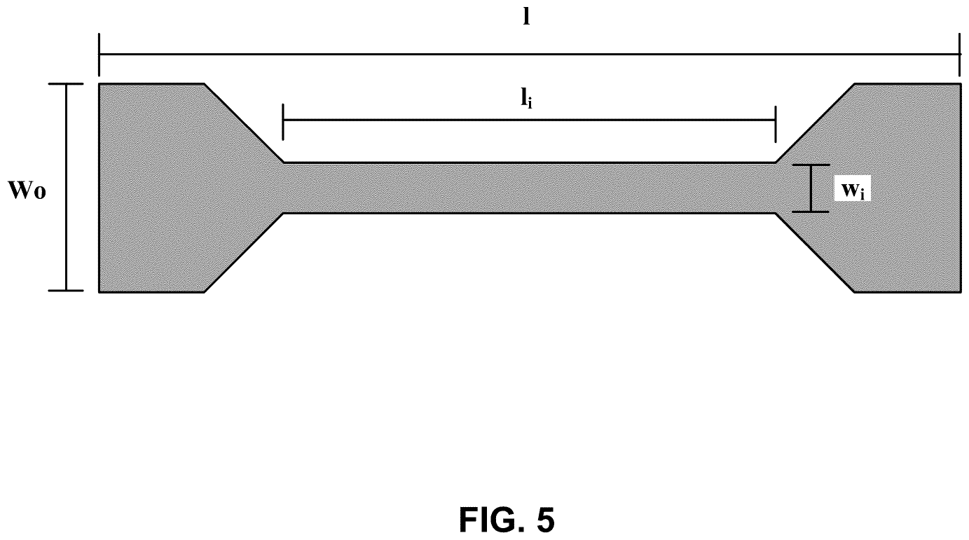

As shown in FIG. 3, FIG. 4 and FIG. 5, each fuse 32 has an input end 31 and an output end 33. The input end 31 may be connected to an input cable 24 which is connected to an input lead 22 adapted to receive current from the high voltage source 20. The output end 33 is connected to an output cable 34, which is series connected to a probe set 44. Optionally, the output cables 34 may be consolidated into a cable bundle 36, but the output cables 34 remain as separate cables within the cable bundle 36, i.e. the output cables 34 operate in parallel relative to each other.

The probe set 44 includes a probe card 40 and a plurality of probes 42, wherein each probe 42 may be adapted to series connect to a slot modulator 52 on a wafer 50.

Optionally, as shown in FIG. 4, the system may further include a carrier printed circuit board (PCB) 60, a plurality of spring-loaded clips 62 connected to output cable extensions 34A, and one or more array alignment stops 64. In this embodiment, the fuse array 30 may be adapted to reversibly attach to the carrier PCB 60, that is, the fuse array 30 is arranged on a card 66 which can be inserted onto the PCB 60 and removed from the PCB 60. In a preferred embodiment, the output cable 34 for each fuse is oriented on the card 66 to align with and connect to the spring-loaded clip 62 which is attached to the output cable extension 34A which then series connects to the probe card 40 or slot modulator 52. The array alignment stops 64 guide the fuse array card 66 placement to orient the fuse array 30 on the carrier PCB 60. In a preferred embodiment, the spring-loaded clip is a spring-loaded beryllium copper clip.

The single input lead 22 is adapted to receive current from the high voltage source 20. The single high-voltage source 20 may include one or more input cables. Examples of known high voltage sources include, but are not limited to, modular high voltage power supply, rack mount and bench top high voltage power supplies, monoblock type, application specific high voltage power supplies, triple output high voltage power supply, quad output high voltage power supply, single output high voltage power supply, single output programmable bipolar high voltage power supply, single output unipolar high voltage power supply, or a source-measure unit (SMU).

Embodiments may include a fuse array that includes a plurality of fuses 32 connected in parallel. In an exemplary embodiment, each fuse 32 is made of a material having a good character of resistance, and may be a single metal, an alloy, aluminum, gold, copper, silver, platinum, palladium, tungsten, titanium, or a combination thereof. Each fuse 32 has a predetermined poling current upper limit. The poling current upper limit will generally be ten times to twenty times the expected poling current. Each fuse has a length, width, and thickness. The length, width and thickness of the fuse will have an influence on the resistance of the fuse, as well as the poling current upper limit. The fuse material, shape, and dimensions can be selected to determine the resistance/temperature at which a fuse will break.

In a preferred embodiment, as shown in FIG. 5, the fuse 32 has a dogbone shape when observed from a top view. The dogbone shape refers to a shape that resembles the bone of a dog, typically with two relatively larger ends connected by a straight and relatively narrower middle section. An exemplary dogbone-shaped fuse will have a poling current upper limit in a range of about 500 nA to about 1000 nA, an outer width wₒ of about 100 μm, an inner width wᵢ between about 2 μm and about 25 μm, an inner length lᵢ between about 50 μm and about 200 μm, a whole length l between about 250 μm and about 400 μm, and a thickness of the dogbone fuse t of about 1 μm. For another example, an exemplary dogbone-shaped fuse may have a polling current upper limit as low as about 150 nA. For another example, an exemplary dogbone-shaped fuse may have a polling current upper limit as high as in a range of about 5,000 nA to about 100,000 nA. In addition, the maximum current of the system may, for example, have a range of about 5 μA to about 10 μA.

The various embodiments may also include the wafer 50 adapted to support the plurality of slot modulator devices 52. One or more (e.g., each) modulator device may be used for modulating a light beam on the whole wafer, although other applications are known in the art and the present invention may be used for any such application. For example, each slot modulator may include, but is not limited to, one of a polymer modulator or a laser modulator. Preferably, each slot modulator device 52 is series connected to one fuse 32 in the fuse array 30 through the output cable of the fuse 34, 34A.

Because the fuses 32 are connected in parallel, when one slot modulator device 52 shorts, the fuse 32 that is series-connected to the shorted slot modulator device 52 may break due to Joule heating. If the fuse series connected to the shorted slot modulator device breaks, the remaining fuses can still function because they are still receiving current and still have voltage drop. When the fuse series connected to the shorted slot modulator breaks, the current to all the other fuses in parallel may remain stable. No voltage drop may be removed from any other slot modulator device connected in parallel. Therefore, the current invention not only provides protection to other devices and the circuit that is connected in parallel, but also keeps other devices working without stopping.

In some embodiments of the above-mentioned various embodiments, the fuse array is attached to a carrier PCB. The carrier PCB increases efficiency related to switching in and out of the fuse array for each poling run.

In some embodiments of the above-mentioned various embodiments, the fuse array will include at least 10,000 fuses connected in parallel. The length and width of the fuse array may have a range between about 5 cm and about 20 cm.

In some embodiments, each slot modulator device is a silicon-organic-hybrid (SOH) slot modulator. Using SOH slot modulator to pole a whole wafer under a single high-voltage source may be efficient in manufacturing.

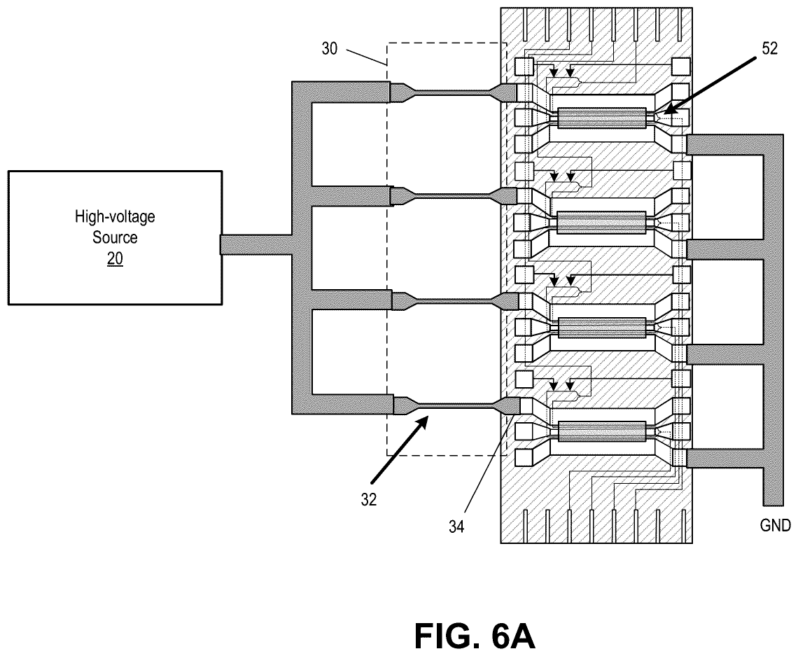

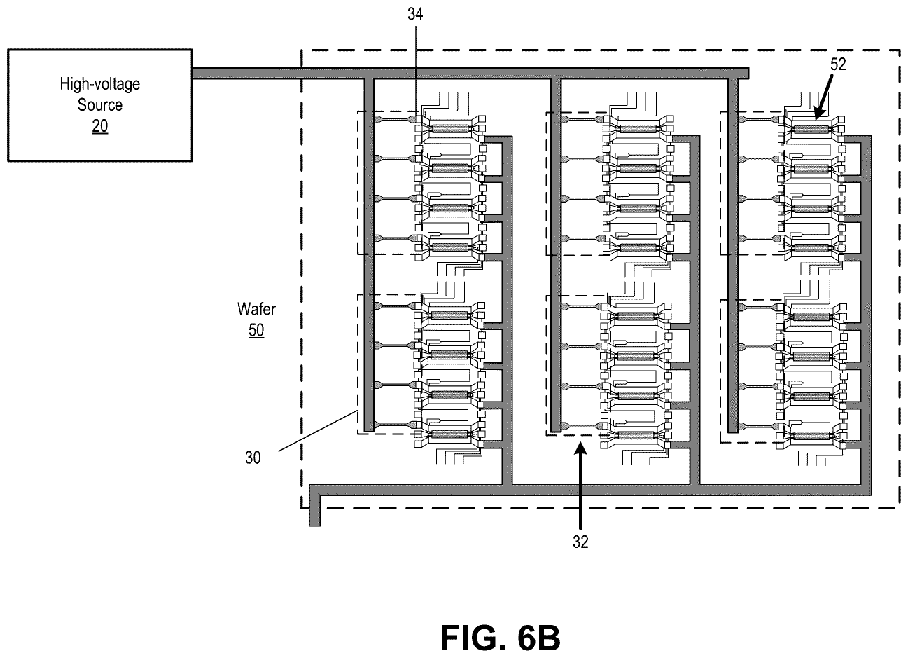

In some embodiments, the output cable 34 from the fuse 32 may be directly series connected to a preselected slot modulator 52, thereby eliminating the probe set 44. For example, in a first embodiment, as shown in FIG. 6A, the system to pole a plurality of slot modulator devices 52 may include one fuse array 30 that includes a plurality of fuses 32. Each fuse 32 in the fuse array 30 is connected in series to a preselected slot modulator device 52 on a wafer 50 without a plurality of probes in the probe set. In a second embodiment, as shown in FIG. 6B, the system to pole a plurality of slot modulator devices 52 may include two or more fuse arrays 30. Each fuse array 30 may include a plurality of fuses 32 connected in parallel. The two or more fuse arrays 30 may connect with each other in parallel, in series, or in a combination of both. Each fuse 32 in the fuse arrays 30 is connected in series to a preselected slot modulator device 52 on a wafer 50 without a plurality of probes in the probe set.

The present invention may provide a solution to overcome the problem of having an entire slot modulator device wafer fail because a single modulator device or fuse shorts on the wafer. The present invention may include a plurality of fuses connected in parallel wherein each fuse is connected in series to one slot modulator device. If one slot modulator device shorts, the fuse that is series connected to the shortened slot modulator device may break due to Joule heating, but the remaining slot modulator device connected in parallel can still function because they are still receiving current and voltage drop. Further, when the one fuse that is series connected to the shortened slot modulator breaks, the current to all the other fuses connected in parallel may remain stable. Therefore, the current invention not only provides protection to other devices and the whole circuit, but also keeps other devices working without stopping.

Unless defined otherwise, all technical and scientific terms used herein have the same meaning as commonly understood by one of ordinary skill in the art to which the presently disclosed subject matter pertains. Representative methods, devices, and materials are described herein, but are not intended to be limiting unless so noted.

The terms “a”, “an”, and “the” refer to “one or more” when used in the subject specification, including the claims.

Unless otherwise indicated, all numbers expressing physical characteristics of the components, quantities of components, conditions, and otherwise used in the specification and claims are to be understood as being modified in all instances by the term “about”. Accordingly, unless indicated to the contrary, the numerical parameters set forth in the instant specification and attached claims are approximations that can vary depending upon the desired properties sought to be obtained by the presently disclosed subject matter.

As used herein, the term “about”, when referring to a value or to a physical dimension or to an amount of mass, weight, time, volume, concentration, or percentage can encompass variations of, in some embodiments ±20%, in some embodiments ±10%, in some embodiments ±5%, in some embodiments ±1%, in some embodiments ±0.5%, and in some embodiments to ±0.1%, from the specified value, as such variations are appropriate in the disclosed application.

It is understood that, in light of a reading of the foregoing description, those with ordinary skill in the art will be able to make changes and modifications to the present invention without departing from the spirit or scope of the invention, as defined herein. For example, those skilled in the art may substitute materials known in the art for materials specified herein without altering the scope of the present invention.

What is claimed is:

1. A method of fabricating an integrated electro-optic phase modulator array, wherein the method comprising:
providing a first substrate, wherein the first substrate comprises an interconnect array;
arranging, on a surface of the first substrate, an array of electro-optic phase modulators, wherein each modulator comprises:
a polymer optical stack,
a semiconductor substrate,
an electric input,
an optical input, and
an optical output; and
wherein, for each modulator, the interconnect array comprises:
an electric interconnect, wherein the electric interconnect connects to a respective electric input,
an electric bypass, wherein the electrical bypass connects at least a pair of adjacent modulators, and
an optical interconnect, wherein the optical interconnect connects a respective optical input and optical output; and
wherein each modulator is series connected to a respective fuse arranged along the electric interconnect between the respective electric input and a voltage source.

2. The method of claim 1, wherein the each modulator is a silicon-organic-hybrid (SOH) slot modulator.

3. The method of claim 1, wherein an active region of the polymer optical stack comprises at least one hyperpolarizable organic chromophore.

4. The method of claim 3, wherein the at least one hyperpolarizable organic chromophore comprises a general formula (I):
D-Π-A (I)
wherein D represents an organic electron-donating group; A represents an organic electron-accepting group having an electron affinity greater than the electron affinity of D; and Π represents a Π-bridge between A and D.

5. The method of claim 3, wherein the at least one hyperpolarizable organic chromophore is poled into alignment.

6. The method of claim 1, wherein the method further comprising:
providing a second substrate, wherein the second substrate comprises a carrier printed circuit board (PCB);
disposing a fuse array on the carrier PCB, wherein the fuse array comprises a plurality of fuses arranged along the electric interconnect, and wherein each fuse arranged along the electric interconnect in the fuse array has an input end series connected to the voltage input lead and an output end series connected to an output cable, and wherein each fuse in the fuse array has a predetermined poling current upper limit at which each fuse will break if the upper limit is exceeded.

7. The method of claim 6, wherein the fuse array is series connected to the voltage source.

8. The method of claim 7, wherein the voltage source is a constant voltage source with high voltage.

9. The method of claim 6, wherein the fuse array comprises equal to or more than 10,000 fuses.

10. The method of claim 1, wherein the fuse arranged along the electric interconnect has a dogbone-shaped top view and has a blow current between about 500 nA and about 1000 nA.

11. The method of claim 1, wherein the fuse arranged along the electric interconnect is made of aluminum or gold.

12. The method of claim 6, wherein the method further comprising:
providing a probe set, wherein the probe set comprises a plurality of probes connected in parallel; and
series connecting each probe in between each fuse arranged along the electric interconnect and each respective electric input of each modulator.

13. The method of claim 1, wherein further comprising:
poling a wafer with the fabricated integrated electro-optic phase modulator array.
